(19) United States
(12) Patent Application Publication
(10) Pub. No.: US 2024/0113662 A1
(43) Pub. Date: Apr. 4, 2024

(54) AMPLIFIER MODULE AND COMMUNICATION APPARATUS

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/471,337

(22) Filed: Sep. 21, 2023

(30) Foreign Application Priority Data
Sep. 29, 2022 (JP) 2022-156525

(51) Int. Cl. H03F 1/02; H03F 1/56; H03F 3/24; H03F 3/60

(52) U.S. Cl. CPC H03F 1/0288; H03F 1/56; H03F 3/245; H03F 3/604

(57) ABSTRACT

An amplifier module includes an antenna that includes four power feed points, and four power amplifiers. Output ends of the four power amplifiers are connected to the four power feed points in a one-to-one relationship. The four power feed points are arranged rotationally symmetrically around a center of the antenna when a main surface of the antenna is viewed in plan.

### CROSS-REFERENCE TO RELATED APPLICATION

This application claims priority to Japanese application no. 2022-156525, filed Sep. 29, 2022, the entire contents of which are hereby incorporated by reference.

### BACKGROUND

### 1. Field

The present disclosure relates to an amplifier module and a communication apparatus.

### 2. Description of the Related Art

A power amplifier circuit includes a first amplifier (carrier amplifier) that amplifies a first signal distributed from an input signal in a region in which the power level of an input signal is equal to or higher than a first level and outputs a second signal, a first transformer that receives the second signal, a second amplifier (peak amplifier) that amplifies a third signal distributed from an input signal in a region in which the power level of an input signal is equal to or higher than a second level, which is higher than the first level, and outputs a fourth signal, and a second transformer that receives the fourth signal, is disclosed.

### SUMMARY

In the power amplifier circuit described above, a back-off amount, which is a power difference between a high output region in which the carrier amplifier and the peak amplifier are in the ON state and a low output region in which only the carrier amplifier is in the ON state, can be ensured.

However, in the case where the power amplifier circuit is connected to an antenna in order that an output signal from the power amplifier circuit is emitted as a circularly polarized wave, a synthesis circuit that synthesizes the second signal and the fourth signal while adjusting phases of the second signal and the fourth signal is needed. Because the output signal is attenuated by the synthesis circuit, a problem of degradation in the efficiency of the power amplifier circuit corresponding to the back-off amount occurs.

Accordingly, it is an object of the present invention to provide an amplifier module and a communication apparatus having high-efficiency, circularly-polarized-wave antenna characteristics.

An amplifier module according to an exemplary aspect of the present disclosure includes an antenna including four power feed points; and four power amplifiers. Output ends of the four power amplifiers are connected to the four power feed points in a one-to-one relationship. The four power feed points are arranged rotationally symmetrically around a center of the antenna when a main surface of the antenna is viewed in plan.

According to the present disclosure, an amplifier module and a communication apparatus having high-efficiency, circularly-polarized-wave antenna characteristics can be provided.

### BRIEF DESCRIPTION OF THE DRAWINGS

FIG. 1 is a configuration diagram of an amplifier module and a communication apparatus according to an exemplary embodiment;

FIG. 2 includes a plan view and a cross-section view of an antenna in the exemplary embodiment;

FIG. 3A is a diagram illustrating states of circuits in an amplifier module according to an example at the time when a first signal is output;

FIG. 3B is a diagram illustrating states of circuits in the amplifier module according to the example at the time when a second signal is output;

FIG. 3C is a diagram illustrating states of circuits in the amplifier module according to the example at the time when a third signal is output;

FIG. 3D is a diagram illustrating states of circuits in the amplifier module according to the example at the time when a fourth signal is output;

FIG. 3E is a graph illustrating the relationship between output power and efficiency of the amplifier module according to the example;

FIG. 4 is a diagram illustrating circularly-polarized-wave antenna characteristics of the amplifier module according to the example;

FIG. 5 is a graph illustrating comparison between intermodulation distortion in the amplifier module according to the example and intermodulation distortion in an amplifier module according to a comparative example;

FIG. 6A is a diagram illustrating states of circuits in an amplifier module according to Modification 1 at the time when a first signal is output;

FIG. 6B is a diagram illustrating states of circuits in the amplifier module according to Modification 1 at the time when a second signal is output;

FIG. 6C is a graph illustrating the relationship between output power and efficiency of the amplifier module according to Modification 1;

FIG. 7 is a configuration diagram of an amplifier module according to Modification 2; and

FIG. 8 is a configuration diagram of an amplifier module according to Modification 3.

### DETAILED DESCRIPTION

Hereinafter, exemplary embodiments of the present disclosure will be described in detail with reference to drawings. The exemplary embodiments described below each illustrate a comprehensive or specific example. The numerical values, shapes, materials, component elements, arrangements of the component elements, manners in which the component elements are connected, and so on illustrated in the exemplary embodiments described below are merely examples and are not intended to limit the present disclosure.

The drawings are schematic diagrams in which emphasis, omission, or ratio adjustment is performed in an appropriate manner in order that the present disclosure is illustrated. The drawings are not necessarily strictly illustrated and may differ from actual shapes, positional relationships, and ratios. In the drawings, substantially the same configurations are denoted by the same reference signs, and repetitive description may be omitted or simplified.

In the following drawings, an X-axis and a Y-axis are axes that are orthogonal to each other on a plane parallel to a main surface of a dielectric substrate. Specifically, in the case where the dielectric substrate has a rectangular shape in plan view, the X-axis is parallel to a first side of the dielectric substrate and the Y-axis is parallel to a second side orthogonal to the first side of the dielectric substrate. Furthermore, a Z-axis is an axis perpendicular to the main surface of the dielectric substrate. A positive direction of the Z-axis indicates an upward direction, and a negative direction of the Z-axis indicates a downward direction.

In a circuit configuration in the present disclosure, “being connected” not only represents being directly connected by a connection terminal and/or a wire conductor but also includes being electrically connected with another circuit element interposed therebetween. “Being connected between A and B” means being connected to both A and B between A and B.

In component arrangement in the present disclosure, “plan view” means viewing an object from the z-axis positive side by orthographic projection of the object onto the xy-plane.

In the present disclosure, terms indicating relationships between elements, such as “parallel”, “perpendicular”, and “distance”, and terms indicating shapes of elements, such as “rectangular”, are not strict expressions but represent substantially equivalent ranges, which include, for example, a difference of a few percent. Furthermore, a state in which “a first direction and a second direction are the same” does not necessarily represent a state in which the angle formed between a direction vector of the first direction and a direction vector of the second direction is exactly 0 degrees but include a state in which the angle formed between the two direction vectors is within a range of plus or minus 10 degrees.

In the present disclosure, a “signal path” represents a transmission line including a wire through which a high frequency signal propagates, an electrode directly connected to the wire, a terminal directly connected to the wire or the electrode, and the like.

### Embodiment

### 1 Configurations of Amplifier Module 1 and Communication Apparatus 3

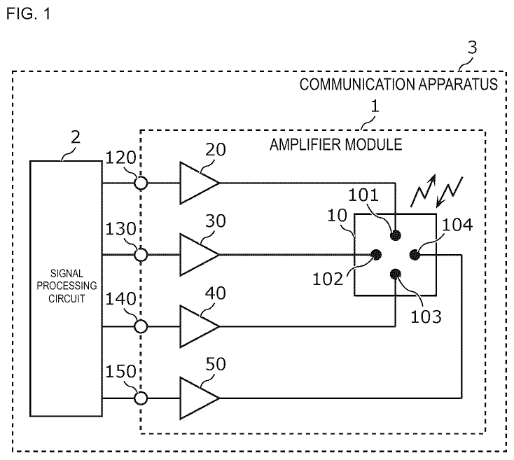

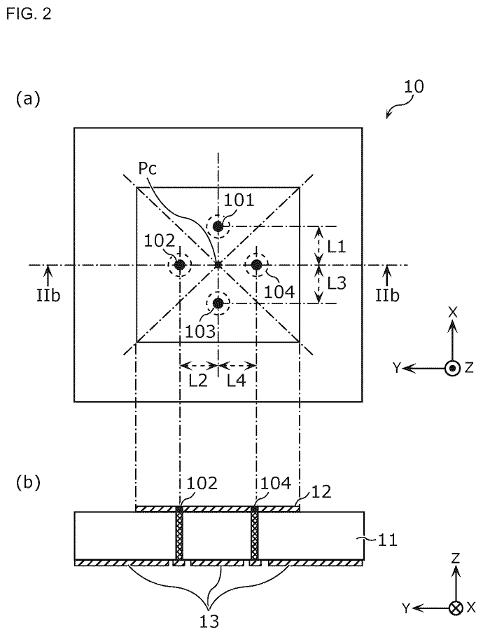

Configurations of an amplifier module 1 and a communication apparatus 3 according to an exemplary embodiment will be described with reference to FIGS. 1 and 2. FIG. 1 is a configuration diagram of the amplifier module 1 and the communication apparatus 3 according to an exemplary embodiment. FIG. 2 includes a plan view and a cross-section view of an antenna 10 according to the exemplary embodiment.

First, a configuration of the communication apparatus 3 will be described. As illustrated in FIG. 1, the communication apparatus 3 according to this exemplary embodiment includes the amplifier module 1 and a signal processing circuit 2.

The signal processing circuit 2 is an example of a circuit that processes a high frequency signal. The signal processing circuit 2 includes a controller that controls the amplifier module 1. Specifically, the signal processing circuit 2 performs signal processing, such as up conversion, on a transmission signal, and outputs a high frequency transmission signal generated by the signal processing to the amplifier module 1. Furthermore, the signal processing circuit 2 controls a power supply voltage and a bias current to be supplied to power amplifiers in the amplifier module 1. Part of or the entire function as the controller of the signal processing circuit 2 may be implemented outside the signal processing circuit 2 or may be implemented, for example, in the amplifier module 1.

The amplifier module 1 includes the antenna 10 and power amplifiers 20, 30, 40, and 50. The amplifier module 1 amplifies high frequency signals supplied through signal input terminals 120, 130, 140, and 150 from the signal processing circuit 2, and emits the amplified high frequency signals through the antenna 10.

The antenna 10 includes four power feed points 101, 102, 103, and 104. Output ends of the four power amplifiers 20, 30, 40, and 50 are connected to the four power feed points 101, 102, 103, and 104 in a one-to-one relationship. Specifically, the output end of the power amplifier 20 is connected to the power feed point 101, the output end of the power amplifier 30 is connected to the power feed point 102, the output end of the power amplifier 40 is connected to the power feed point 103, and the output end of the power amplifier 50 is connected to the power feed point 104.

As illustrated in FIG. 2, the antenna 10 includes a dielectric substrate 11, a ground planar conductor 13, and a power-feed planar conductor 12.

The dielectric substrate 11 has a multilayer structure in which a dielectric material is filled in between the ground planar conductor 13 and the power-feed planar conductor 12. The dielectric substrate 11 may be, for example, a low temperature co-fired ceramics (LTCC) substrate, a printed board, or the like. The dielectric substrate 11 may be simply a space in which no dielectric material is filled. In this case, a structure supporting the power-feed planar conductor 12 is required.

The ground planar conductor 13 is a planar conductor that is set to a ground potential and formed on a main surface on the rear side (Z-axis negative direction) of the dielectric substrate 11 so as to be substantially parallel to the main surface of the dielectric substrate 11.

The power-feed planar conductor 12 is a planar conductor that is formed on a main surface on the front side (Z-axis positive direction) of the dielectric substrate 11 so as to be opposite (substantially parallel to) the ground planar conductor 13. The power-feed planar conductor 12 and the ground planar conductor 13 correspond to the main surfaces of the antenna 10 that are opposite to each other.

The high frequency signals output from the power amplifiers 20 to 50 are input to signal input terminals arranged on the rear side of the dielectric substrate 11. The signal input terminals are connected to the four power feed points 101, 102, 103, and 104, which are arranged on the power-feed planar conductor 12, with power feed via conductors formed inside the dielectric substrate 11, interposed therebetween.

The four power feed points 101, 102, 103, and 104 are arranged rotationally symmetrical around a center Pc of the antenna 10 when a main surface (power-feed planar conductor 12) of the antenna 10 is viewed in plan (when the negative side is viewed from the Z-axis positive side).

The center Pc of the antenna 10 is defined as a point at which two diagonal lines of the power-feed planar conductor 12 intersect when the power-feed planar conductor 12 is viewed in plan. Furthermore, in the case where the power-feed planar conductor 12 is not rectangular, the center Pc of the antenna 10 is defined as the center of gravity of the power-feed planar conductor 12.

Accordingly, since the four power feed points 101 to 104 are arranged rotationally symmetrical around the center Pc, the phase difference between two signals input to two power feed points that are adjacent to each other in the rotation direction is substantially 90 degrees. Thus, by turning on and off the four power amplifiers 20 to 50 in accordance with output power, without arranging a synthesis circuit for adjusting phases of output signals from the power amplifiers 20 to 50 and synthesizing the phase-adjusted output signals, impedances of the power amplifiers 20 to 50 can be converted without any loss due to a synthesis circuit. Consequently, the amplifier module 1 having high-efficiency, circularly-polarized-wave antenna characteristics corresponding to a back-off amount can be provided.

Each of the distance L1 between the power feed point 101 and the center Pc, the distance L2 between the power feed point 102 and the center Pc, the distance L3 between the power feed point 103 and the center Pc, and the distance L4 between the power feed point 104 and the center Pc is less than or equal to λ/4, where the wavelength at the dielectric substrate 11 of a high frequency signal input to the antenna 10 is represented by λ. Desirably, each of the distances L1, L2, L3, and L4 is λ/4.

Accordingly, since the phase difference between two signals input to two power feed points that are adjacent to each other in the rotation direction can be set to 90 degrees with high precision, the amplifier module 1 can have high-efficiency, circular-polarized-wave antenna characteristics corresponding to a back-off amount and can suppress a harmonic wave distortion component with high accuracy.

The configuration of the antenna illustrated in FIG. 2 is an illustrative configuration of an antenna according to the present disclosure, and the antenna characterized in that the four power feed points 101 to 104 are arranged rotationally symmetrical around the center Pc should not be construed as limiting to the antenna 10 illustrated in FIG. 2.

### 2 Configuration of Amplifier Module 1A According to Example

Next, a configuration and an operation of an amplifier module 1A in the case where four power amplifiers are Doherty amplifiers will be described.

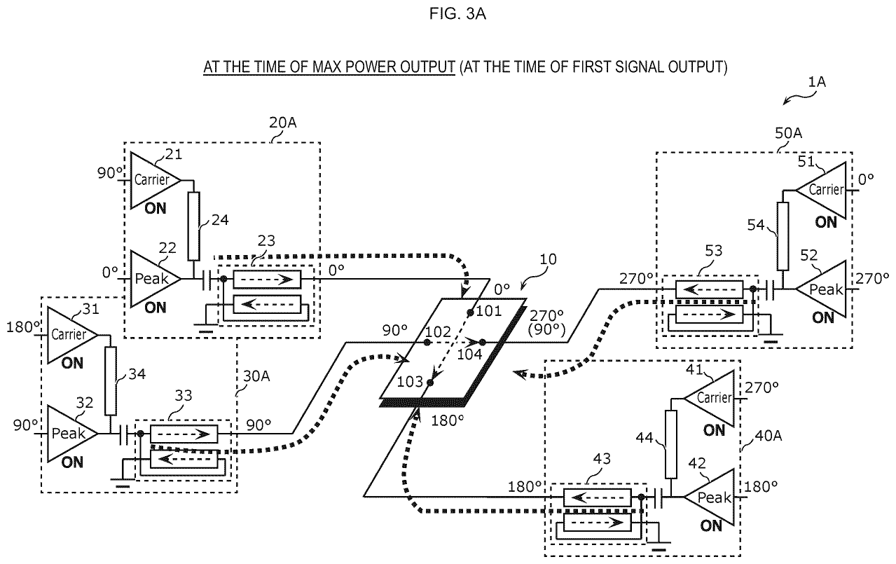

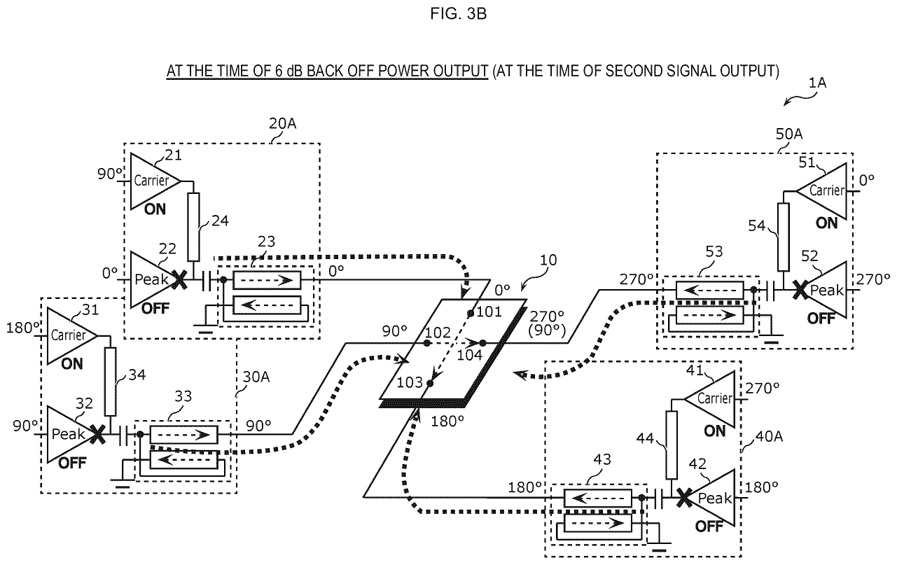

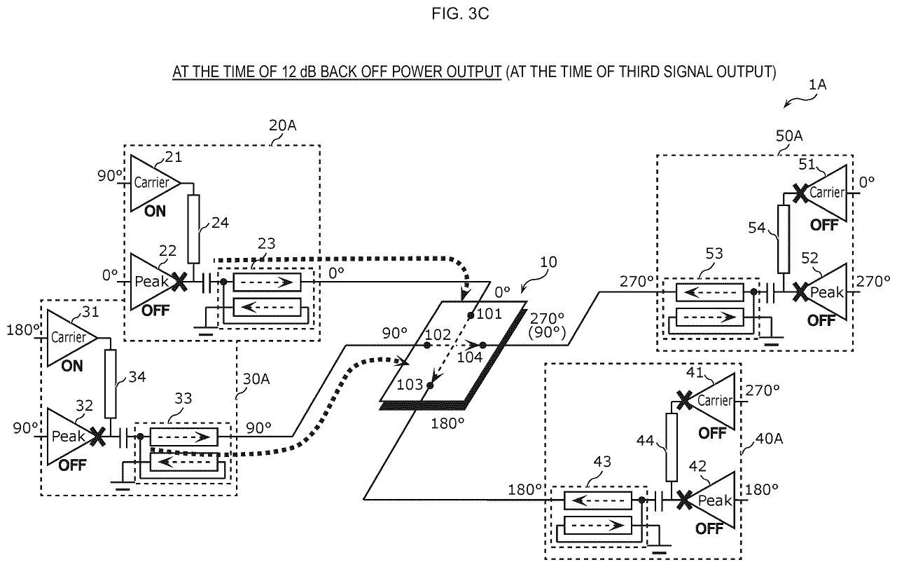

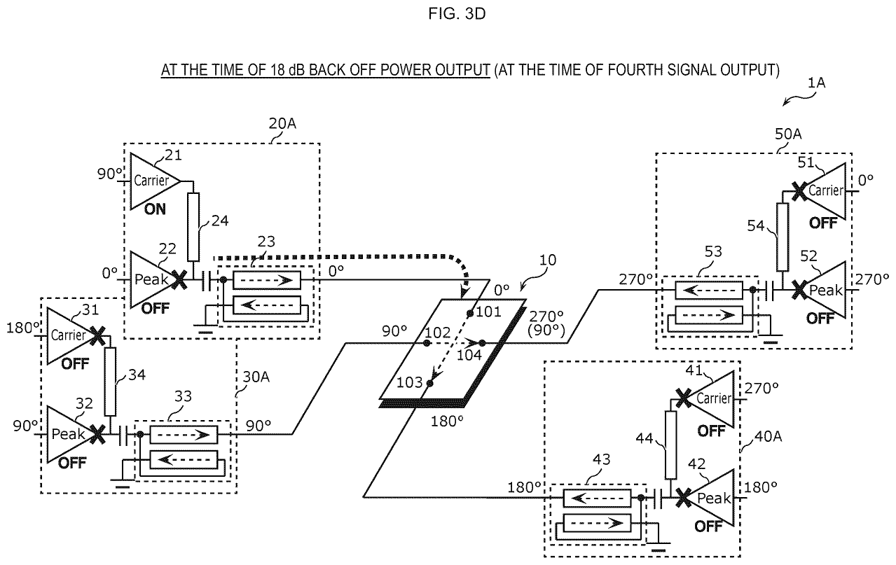

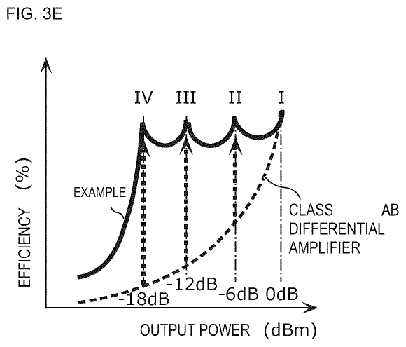

FIG. 3A is a diagram illustrating states of circuits in the amplifier module 1A according to an example at the time when a first signal is output. FIG. 3B is a diagram illustrating the states of the circuits in the amplifier module 1A according to the example at the time when a second signal is output. FIG. 3C is a diagram illustrating the states of the circuits in the amplifier module 1A according to the example at the time when a third signal is output. FIG. 3D is a diagram illustrating the states of the circuits in the amplifier module 1A according to the example at the time when a fourth signal is output. FIG. 3E is a graph illustrating the relationship between output power and efficiency of the amplifier module 1A according to the example.

As illustrated in FIGS. 3A to 3D, the amplifier module 1A according to the example includes the antenna 10 and power amplifiers 20A, 30A, 40A, and 50A. The amplifier module 1A according to the example is different from the amplifier module 1 according to the exemplary embodiment in configurations of the four power amplifiers. Hereinafter, explanation of the configuration of the antenna 10 in the amplifier module 1A according to the example, which is the same as that in the amplifier module 1 according to the embodiment, will be omitted, and configurations of the power amplifiers 20A to 50A, which are different from those in the amplifier module 1 according to the exemplary embodiment, will be mainly described.

In the antenna 10, the power feed points 101 to 104 are arranged around the center Pc in the order of the power feed point 101 (first power feed point), the power feed point 102 (second power feed point), the power feed point 103 (third power feed point), and the power feed point 104 (fourth power feed point) in the rotation direction.

The power amplifier 20A is an example of a first power amplifier and includes a carrier amplifier 21, a peak amplifier 22, a ¼ wavelength transmission line 24, and an impedance conversion circuit 23.

Each of the carrier amplifier 21 and the peak amplifier 22 includes an amplifier transistor. The amplifier transistor is, for example, a bipolar transistor such as a heterojunction bipolar transistor (HBT) or a field effect transistor such as a metal-oxide-semiconductor field effect transistor (MOSFET).

The carrier amplifier 21 is an example of a first carrier amplifier. The carrier amplifier 21 is, for example, a Class A (or Class AB) amplifier circuit that is capable of performing an amplifying operation for all the power levels of an input high frequency signal and, in particular, is capable of performing a high-efficiency amplifying operation in a low output region and an intermediate output region. The carrier amplifier 21 is not limited to a carrier amplifier as long as it is a Class A (or Class AB) amplifier circuit. The phase of a high frequency signal input to the carrier amplifier 21 is advanced from the phase of a high frequency signal input to the peak amplifier 22 by 90 degrees.

Herein, the term efficiency represents power-added efficiency.

The peak amplifier 22 is an example of a first peak amplifier. The peak amplifier 22 is, for example, a Class C amplifier circuit that is capable of performing an amplifying operation in a region in which the power level of an input high frequency signal is high. Since a bias voltage lower than the bias voltage applied to the amplifier transistor included in the carrier amplifier 21 is applied to the amplifier transistor included in the peak amplifier 22, the output impedance decreases as the power level of a high frequency signal increases. Thus, the peak amplifier 22 is capable of performing a low-distortion amplifying operation in a high output region. The peak amplifier 22 is not limited to a peak amplifier as long as it is a Class C amplifier circuit.

The ¼ wavelength transmission line 24 is connected between an output terminal of the carrier amplifier 21 and an output terminal of the peak amplifier 22. The ¼ wavelength transmission line 24 shifts the phase of a signal output from the carrier amplifier 21 by −90 degrees (phase is delayed by 90 degrees). Due to the arrangement of the ¼ wavelength transmission line 24, the phase of a signal output from the carrier amplifier 21 and the phase of a signal output from the peak amplifier 22 become the same. Thus, synthesis of the current of a signal output from the carrier amplifier 21 and the current of a signal output from the peak amplifier 22 can be achieved.

The impedance conversion circuit 23 includes a main line and a sub-line. The impedance conversion circuit 23 shifts phase at both ends of the impedance conversion circuit 23 and converts impedance at a predetermined conversion ratio. The main line is, for example, a transmission line having a ⅛ wavelength or 1/16 wavelength. One end of the main line is connected to one end of the ¼ wavelength transmission line 24, and the other end of the main line is connected to the power feed point 101. The other end of the ¼ wavelength transmission line 24 is connected to an output end of the carrier amplifier 21. The sub-line is, for example, a transmission line having a ⅛ wavelength or 1/16 wavelength. One end of the sub-line is connected to the one end of the main line, and the other end of the sub-line is connected to the ground. A first direction from the one end to the other end of the main line and a second direction from the other end to the one end of the sub-line are the same.

With the above-mentioned configuration of the power amplifier 20A, the output impedance of the carrier amplifier 21 at the time of small signal input is higher than that at the time of large signal input. That is, at the time of small signal input, the peak amplifier 22 is in the OFF state, and the output impedance of the carrier amplifier 21 is high. Thus, the power amplifier 20A can perform a high-efficiency operation.

In contrast, at the time of large signal input, due to operations of the carrier amplifier 21 and the peak amplifier 22, a large power signal can be output, and the output impedance of the peak amplifier 22 is low. Thus, signal distortion can be suppressed.

The power amplifier 20A may include a phase-shift circuit that shifts the phase of an input high frequency signal on each of the input side of the carrier amplifier 21 and the input side of the peak amplifier 22.

Hereinafter, explanation of configurations of the power amplifiers 30A, 40A, and 50A that are the same as the configuration of the power amplifier 20A will be omitted, and differences will be mainly described.

The power amplifier 30A is an example of a second power amplifier and includes a carrier amplifier 31, a peak amplifier 32, a ¼ wavelength transmission line 34, and an impedance conversion circuit 33.

Each of the carrier amplifier 31 and the peak amplifier 32 includes an amplifier transistor.

The carrier amplifier 31 is an example of a second carrier amplifier. The carrier amplifier 31 is, for example, a Class A (or Class AB) amplifier circuit and, in particular, is capable of performing a high-efficiency amplifying operation in a low output region and an intermediate output region. The phase of a high frequency signal input to the carrier amplifier 31 is advanced from the phase of a high frequency signal input to the peak amplifier 32 by 90 degrees.

The peak amplifier 32 is an example of a second peak amplifier and is, for example, a Class C amplifier circuit. The peak amplifier 32 is capable of performing a low-distortion amplifying operation in a high output region. Furthermore, the phase of a high frequency signal input to the peak amplifier 32 is advanced from the phase of a high frequency signal input to the peak amplifier 22 by 90 degrees.

The ¼ wavelength transmission line 34 is connected between an output terminal of the carrier amplifier 31 and an output terminal of the peak amplifier 32. The ¼ wavelength transmission line 34 allows the current of a signal output from the carrier amplifier 31 and the current of a signal output from the peak amplifier 32 to be synthesized.

The impedance conversion circuit 33 includes a main line and a sub-line. The impedance conversion circuit 33 shifts phase at both ends of the impedance conversion circuit 33 and converts impedance at a predetermined conversion ratio. One end of the main line is connected to one end of the ¼ wavelength transmission line 34 and the other end of the main line is connected to the power feed point 102. The other end of the ¼ wavelength transmission line 34 is connected to an output end of the carrier amplifier 31.

With the above-mentioned configuration of the power amplifier 30A, at the time of small signal input, the peak amplifier 32 is in the OFF state and the output impedance of the carrier amplifier 31 is higher than that at the time of large signal input. Thus, the power amplifier 30A can perform a high-efficiency operation.

In contrast, at the time of large signal input, due to operations of the carrier amplifier 31 and the peak amplifier 32, a large power signal can be output, and the output impedance of the peak amplifier 32 is low. Thus, signal distortion can be suppressed.

The power amplifier 30A may include a phase-shift circuit that shifts the phase of an input high frequency signal on each of the input side of the carrier amplifier 31 and the input side of the peak amplifier 32.

The power amplifier 40A is an example of a third power amplifier and includes a carrier amplifier 41, a peak amplifier 42, a ¼ wavelength transmission line 44, and an impedance conversion circuit 43.

Each of the carrier amplifier 41 and the peak amplifier 42 includes an amplifier transistor.

The carrier amplifier 41 is an example of a third carrier amplifier. The carrier amplifier 41 is, for example, a Class A (or Class AB) amplifier circuit and, in particular, is capable of performing a high-efficiency amplifying operation in a low output region and an intermediate output region. The phase of a high frequency signal input to the carrier amplifier 41 is advanced from the phase of a high frequency signal input to the peak amplifier 42 by 90 degrees.

The peak amplifier 42 is an example of a third peak amplifier and is, for example, a Class C amplifier circuit. The peak amplifier 42 is capable of performing a low-distortion amplifying operation in a high output region. Furthermore, the phase of a high frequency signal input to the peak amplifier 42 is advanced from the phase of a high frequency signal input to the peak amplifier 32 by 90 degrees.

The ¼ wavelength transmission line 44 is connected between an output terminal of the carrier amplifier 41 and an output terminal of the peak amplifier 42. The ¼ wavelength transmission line 44 allows the current of a signal output from the carrier amplifier 41 and the current of a signal output from the peak amplifier 42 to be synthesized.

The impedance conversion circuit 43 includes a main line and a sub-line. The impedance conversion circuit 43 shifts phase at both ends of the impedance conversion circuit 43 and converts impedance at a predetermined conversion ratio. One end of the main line is connected to one end of the ¼ wavelength transmission line 44 and the other end of the main line is connected to the power feed point 103 (third power feed point). The other end of the ¼ wavelength transmission line 44 is connected to an output end of the carrier amplifier 41.

With the above-mentioned configuration of the power amplifier 40A, at the time of small signal input, the peak amplifier 42 is in the OFF state and the output impedance of the carrier amplifier 41 is higher than that at the time of large signal input. Thus, the power amplifier 40A can perform a high-efficiency operation.

In contrast, at the time of large signal input, due to operations of the carrier amplifier 41 and the peak amplifier 42, a large power signal can be output, and the output impedance of the peak amplifier 42 is low. Thus, signal distortion can be suppressed.

The power amplifier 40A may include a phase-shift circuit that shifts the phase of an input high frequency signal on each of the input side of the carrier amplifier 41 and the input side of the peak amplifier 42.

The power amplifier 50A is an example of a fourth power amplifier and includes a carrier amplifier 51, a peak amplifier 52, a ¼ wavelength transmission line 54, and an impedance conversion circuit 53.

Each of the carrier amplifier 51 and the peak amplifier 52 includes an amplifier transistor.

The carrier amplifier 51 is an example of a fourth carrier amplifier. The carrier amplifier 51 is, for example, a Class A (or Class AB) amplifier circuit and, in particular, is capable of performing a high-efficiency amplifying operation in a low output region and an intermediate output region. The phase of a high frequency signal input to the carrier amplifier 51 is advanced from the phase of a high frequency signal input to the peak amplifier 52 by 90 degrees.

The peak amplifier 52 is an example of a fourth peak amplifier and is, for example, a Class C amplifier circuit. The peak amplifier 52 is capable of performing a low-distortion amplifying operation in a high output region. Furthermore, the phase of a high frequency signal input to the peak amplifier 52 is advanced from the phase of a high frequency signal input to the peak amplifier 42 by 90 degrees.

The ¼ wavelength transmission line 54 is connected between an output terminal of the carrier amplifier 51 and an output terminal of the peak amplifier 52. The ¼ wavelength transmission line 54 allows the current of a signal output from the carrier amplifier 51 and the current of a signal output from the peak amplifier 52 to be synthesized.

The impedance conversion circuit 53 includes a main line and a sub-line. The impedance conversion circuit 53 shifts phase at both ends of the impedance conversion circuit 53 and converts impedance at a predetermined conversion ratio. One end of the main line is connected to one end of the ¼ wavelength transmission line 54 and the other end of the main line is connected to the power feed point 104. The other end of the ¼ wavelength transmission line 54 is connected to an output end of the carrier amplifier 51.

With the above-mentioned configuration of the power amplifier 50A, at the time of small signal input, the peak amplifier 52 is in the OFF state and the output impedance of the carrier amplifier 51 is higher than that at the time of large signal input. Thus, the power amplifier 50A can perform a high-efficiency operation.

In contrast, at the time of large signal input, due to operations of the carrier amplifier 51 and the peak amplifier 52, a large power signal can be output, and the output impedance of the peak amplifier 52 is low. Thus, signal distortion can be suppressed.

The power amplifier 50A may include a phase-shift circuit that shifts the phase of an input high frequency signal on each of the input side of the carrier amplifier 51 and the input side of the peak amplifier 52.

Although each of the power amplifiers 20A to 50A has a configuration to synthesize currents of output from the carrier amplifier and output from the peak amplifier by using the ¼ wavelength transmission line and the impedance conversion circuit, each of the power amplifiers 20A to 50A may have a configuration to synthesize voltages of output from the carrier amplifier and output from the peak amplifier by using a transformer.

An operation of the amplifier module 1A for output power will be described below.

First, as illustrated in FIG. 3A, at the time when the first signal is output (at the time of Max Power output), all the carrier amplifiers 21, 31, 41, and 51 and all the peak amplifiers 22, 32, 42, and 52 operate (ON). In this case, the output impedance of each of the carrier amplifiers 21 to 51 and the peak amplifiers 22 to 52 is Z_{L}.

Next, as illustrated in FIG. 3B, at the time when the second signal is output (at the time of 6 dB Back off Power output), at which the power is lower than the power at which the first signal is output, all the carrier amplifiers 21 to 51 operate (ON) and none of the peak amplifiers 22 to 52 operates (OFF). In this case, the output impedance of each of the carrier amplifiers 21 to 51 is 2 Z_{L}. At this time, the output impedances of the peak amplifiers 22 to 52 are in an opened state. That is, at the time when the second signal is output, the peak amplifiers 22 to 52 enter the OFF state, and the output impedances of the carrier amplifiers 21 to 51 increase. Thus, the back off amount of 6 dB can be obtained, and the amplifier module 1A can perform a high-efficiency operation.

Next, as illustrated in FIG. 3C, at the time when the third signal is output (at the time of 12 dB Back off Power output), at which the power is lower than the power at which the second signal is output, the carrier amplifiers 21 and 31 operate (ON) and none of the carrier amplifiers 41 and 51 and the peak amplifiers 22 to 52 operates (OFF). In this case, the output impedance of each of the carrier amplifiers 21 and 31 is 4 Z_{L}. At this time, the output impedances of the carrier amplifiers 41 and 51 and the peak amplifiers 22 to 52 are in the opened state. That is, at the time when the third signal is output, the carrier amplifiers 41 and 51 and the peak amplifiers 22 to 52 enter the OFF state, and the output impedances of the carrier amplifiers 21 and 31 increase. Thus, the back off amount of 12 dB can be obtained, and the amplifier module 1A can perform a high-efficiency operation.

Next, as illustrated in FIG. 3D, at the time when the fourth signal is output (at the time of 18 dB Back off Power output), at which the power is lower than the power at which the third signal is output, the carrier amplifier 21 operates (ON) and none of the carrier amplifiers 31, 41, and 51 and the peak amplifiers 22 to 52 operates (OFF). In this case, the output impedance of the carrier amplifier 21 is 8 Z_{L}. At this time, the output impedances of the carrier amplifiers 31, 41, and 51 and the peak amplifiers 22 to 52 are in the opened state. That is, at the time when the fourth signal is output, the carrier amplifiers 31, 41, and 51 and the peak amplifiers 22 to 52 enter the OFF state, and the output impedance of the carrier amplifier 21 increases. Thus, the back off amount of 18 dB can be obtained, and the amplifier module 1A can perform a high-efficiency operation.

In FIG. 3E, the horizontal axis represents the power level of a signal output from the amplifier module 1A, and the vertical axis represents the efficiency (power-added efficiency) of the amplifier module 1A.

When the power level of a high frequency signal output from the amplifier module 1A decreases from a first power value (first signal output: I in FIG. 3E) to a second power value (second signal output: II in FIG. 3E), the impedances of the carrier amplifiers 21 to 51, which are in the ON state, increase. Thus, at the time when the second signal is output, high efficiency can be achieved compared to the case where all the carrier amplifiers 21 to 51 and all the peak amplifiers 22 to 52 operate in the ON state (in FIG. 3E, indicated as a Class AB amplifier).

Furthermore, when the power level of a high frequency signal output from the amplifier module 1A decreases from the second power value (second signal output: II in FIG. 3E) to a third power value (third signal output: III in FIG. 3E), the impedances of the carrier amplifiers 21 and 31, which are in the ON state, further increase. Thus, at the time when the third signal is output, high efficiency can be achieved compared to the case where all the carrier amplifiers 21 to 51 and all the peak amplifiers 22 to 52 operate in the ON state (in FIG. 3E, indicated as the Class AB amplifier).

When the power level of a high frequency signal output from the amplifier module 1A decreases from the third power value (third signal output: III in FIG. 3E) to a fourth power value (fourth signal output: IV in FIG. 3E), the impedance of the carrier amplifier 21, which is in the ON state, further increases. Thus, at the time when the fourth signal is output, high efficiency can be achieved compared to the case where all the carrier amplifiers 21 to 51 and all the peak amplifiers 22 to 52 operate in the ON state (in FIG. 3E, indicated as the Class AB amplifier).

That is, since the amplifier module 1A ensures the back off amount of 6 dB in each stage, that is, 18 dB in total, the amplifier module 1A can perform a high-efficiency operation while reducing degradation in the efficiency to the minimum level.

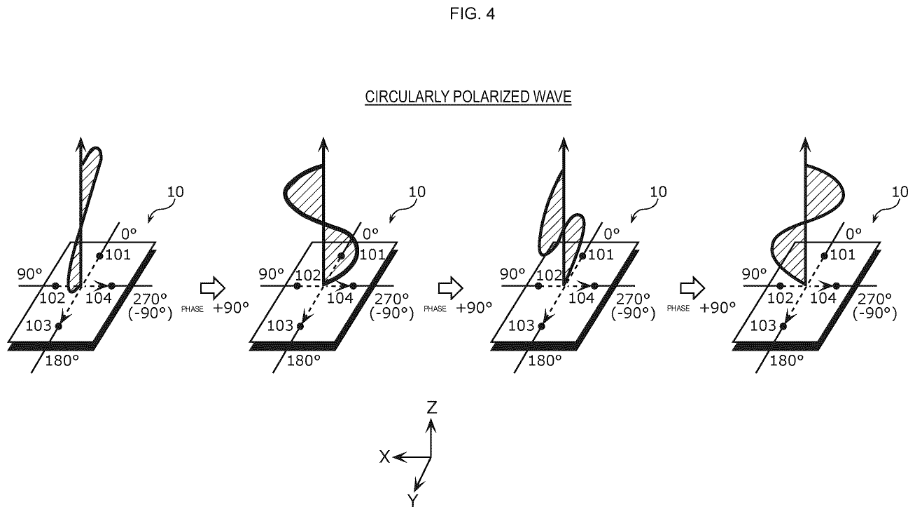

FIG. 4 is a diagram illustrating circularly-polarized-wave antenna characteristics of the amplifier module 1A according to the example. As illustrated in FIG. 4, the amplifier module 1A according to this example exhibits so-called circularly-polarized-wave antenna characteristics in which an electric field and a magnetic field rotate around the Z-axis as a rotation axis. This is because at the times when the first to fourth signals are output, high frequency signals with a phase difference of 90 degrees are supplied to two power feed points that are adjacent to each other among the power feed points 101 to 104 arranged rotationally symmetrical around the center Pc.

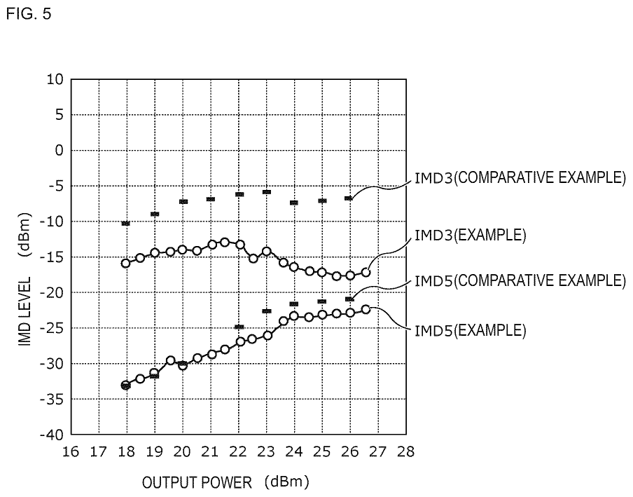

FIG. 5 is a graph illustrating comparison between intermodulation distortion in the amplifier module according to this example and intermodulation distortion in an amplifier module according to a comparative example. In FIG. 5, characteristics of third intermodulation distortion (IMD3) and fifth intermodulation distortion (IMD5) with respect to output power in the amplifier module according to this example and in the amplifier module according to the comparative example are illustrated.

In the amplifier module 1A according to this example illustrated in FIG. 5, for example, a bias current supplied to the carrier amplifier 21 of the power amplifier 20A is set to be larger than a bias current supplied to the carrier amplifier 41 of the power amplifier 40A and a bias current supplied to the peak amplifier 22 of the power amplifier 20A is set to be larger than a bias current supplied to the peak amplifier 42 of the power amplifier 40A. Furthermore, a bias current supplied to the carrier amplifier 31 of the power amplifier 30A is set to be larger than a bias current supplied to the carrier amplifier 51 of the power amplifier 50A and a bias current supplied to the peak amplifier 32 of the power amplifier 30A is set to be larger than a bias current supplied to the peak amplifier 52 of the power amplifier 50A.

The amplifier module according to the comparative example has the same circuit configuration as the circuit configuration of the amplifier module 1A according to this example. However, in the amplifier module according to the comparative example, the value of a bias current supplied to the carrier amplifier 21 of the power amplifier 20A is the same as the value of a bias current supplied to the carrier amplifier 41 of the power amplifier 40A, and the value of a bias current supplied to the peak amplifier 22 of the power amplifier 20A is the same as the value of a bias current supplied to the peak amplifier 42 of the power amplifier 40A. Furthermore, the value of a bias current supplied to the carrier amplifier 31 of the power amplifier 30A is the same as the value of a bias current supplied to the carrier amplifier 51 of the power amplifier 50A, and the value of a bias current supplied to the peak amplifier 32 of the power amplifier 30A is the same as the value of a bias current supplied to the peak amplifier 52 of the power amplifier 50A.

In the amplifier module 1A according to this example, input/output characteristics of the power amplifier 20A can be set to a gain compression type, and input/output characteristics of the power amplifier 40A can be set to a gain expansion type. Furthermore, input/output characteristics of the power amplifier 30A can be set to a gain compression type, and input/output characteristics of the power amplifier 50A can be set to a gain expansion type. Accordingly, a nonlinear distortion component generated from the power amplifier 20A and a nonlinear distortion component generated from the power amplifier 40A can cancel each other out, and a nonlinear distortion component generated from the power amplifier 30A and a nonlinear distortion component generated from the power amplifier 50A can cancel each other out. Thus, as illustrated in FIG. 5, IMD3 and IMD5 components can be suppressed.

### 3 Configuration of Amplifier Module 1B According to Modification 1

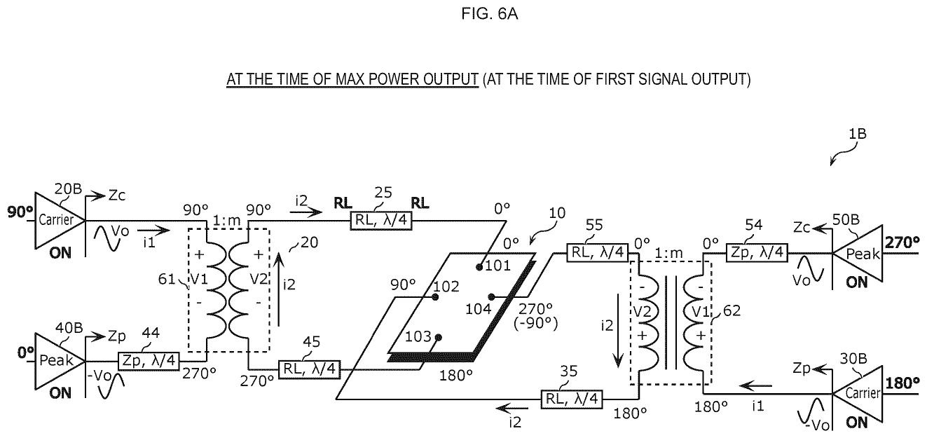

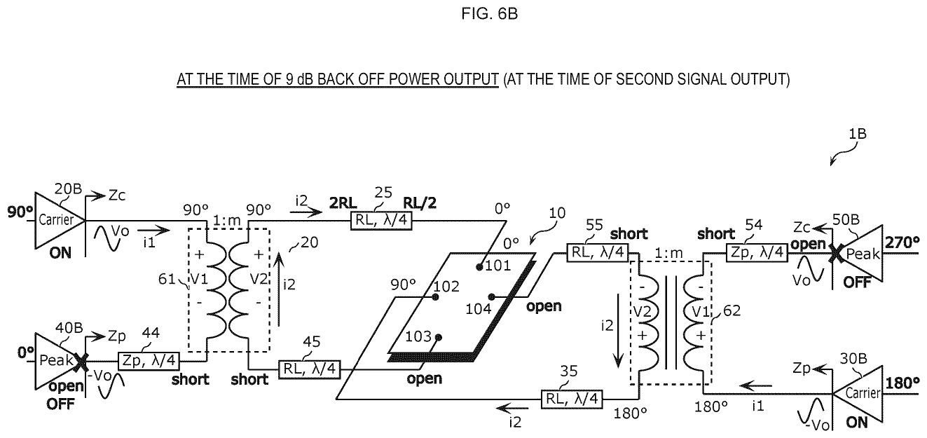

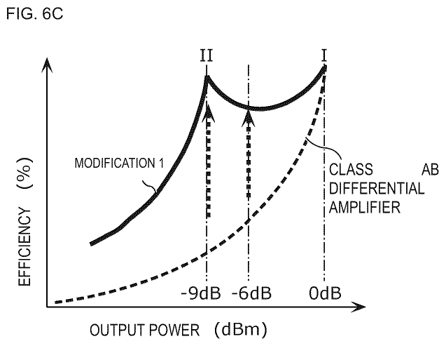

FIG. 6A is a diagram illustrating states of circuits in an amplifier module 1B according to Modification 1 at the time when a first signal is output. FIG. 6B is a diagram illustrating the states of circuits in the amplifier module 1B according to Modification 1 at the time when a second signal is output. FIG. 6C is a graph illustrating the relationship between output power and efficiency of the amplifier module 1B according to Modification 1.

As illustrated in FIGS. 6A and 6B, the amplifier module 1B according to Modification 1 includes the antenna 10, carrier amplifiers 20B and 30B, peak amplifiers 40B and 50B, transformers 61 and 62, and ¼ wavelength transmission lines 25, 35, 44, 45, 54, and 55. The amplifier module 1B according to this modification is different from the amplifier module 1 according to the exemplary embodiment in configurations of four power amplifiers. Hereinafter, explanation of the configuration of the antenna 10 in the amplifier module 1B according to this modification, which is the same as that in the amplifier module 1 according to the exemplary embodiment, will be omitted, and configurations of the carrier amplifiers 20B and 30B and the peak amplifiers 40B and 50B, which are different from those in the amplifier module 1 according to the exemplary embodiment, will be mainly described.

The carrier amplifier 20B is an example of a first power amplifier, and an output end of the carrier amplifier 20B is connected to the power feed point 101 with the transformer 61 and the ¼ wavelength transmission line 25 interposed therebetween.

The carrier amplifier 30B is an example of a second power amplifier, and an output end of the carrier amplifier 30B is connected to the power feed point 102 with the transformer 62 and the ¼ wavelength transmission line 35 interposed therebetween.

The peak amplifier 40B is an example of a third power amplifier, and an output end of the peak amplifier 40B is connected to the power feed point 103 with the transformer 61 and the ¼ wavelength transmission lines 44 and 45 interposed therebetween.

The peak amplifier 50B is an example of a fourth power amplifier, and an output end of the peak amplifier 50B is connected to the power feed point 104 with the transformer 62 and the ¼ wavelength transmission lines 54 and 55 interposed therebetween.

The ¼ wavelength transmission line 44 is arranged between the output end of the peak amplifier 40B and the other end of an input-side coil of the transformer 61. The ¼ wavelength transmission line 54 is arranged between the output end of the peak amplifier 50B and the other end of an input-side coil of the transformer 62.

The transformer 61 includes the input-side coil and an output-side coil. One end of the input-side coil is connected to the output end of the carrier amplifier 20B, and the other end of the input-side coil is connected to the output end of the peak amplifier 40B with the ¼ wavelength transmission line 44 interposed therebetween. One end of the output-side coil is connected to the power feed point 101 with the ¼ wavelength transmission line 25 interposed therebetween, and the other end of the output-side coil is connected to the power feed point 103 with the ¼ wavelength transmission line 45 interposed therebetween.

The transformer 62 includes the input-side coil and an output-side coil. One end of the input-side coil is connected to the output end of the carrier amplifier 30B, and the other end of the input-side coil is connected to the output end of the peak amplifier 50B with the ¼ wavelength transmission line 54 interposed therebetween. One end of the output-side coil is connected to the power feed point 102 with the ¼ wavelength transmission line 35 interposed therebetween, and the other end of the output-side coil is connected to the power feed point 104 with the ¼ wavelength transmission line 55 interposed therebetween.

With the above-mentioned configurations of the carrier amplifier 20B and the peak amplifier 40B, the output impedance of the carrier amplifier 20B at the time of small signal input is higher than that at the time of large signal input. That is, at the time of small signal input, the peak amplifier 40B is in the OFF state, and the output impedance of the carrier amplifier 20B is high. Thus, the carrier amplifier 20B can perform a high-efficiency operation.

In contrast, at the time of large signal input, due to operations of the carrier amplifier 20B and the peak amplifier 40B, a large power signal can be output, and the output impedance of the peak amplifier 40B is low. Thus, signal distortion can be suppressed.

The phase of a high frequency signal input to the carrier amplifier 20B is advanced from the phase of a high frequency signal input to the peak amplifier 40B by 90 degrees, and the signal is supplied to the power feed point 101 by being delayed by 90 degrees due to the ¼ wavelength transmission line 25. Furthermore, the phase of a high frequency signal input to the peak amplifier 40B is delayed by 90 degrees due to the ¼ wavelength transmission line 44, and the signal is supplied to the power feed point 103 by being further delayed by 90 degrees due to the ¼ wavelength transmission line 45. That is, the phase of the high frequency signal supplied to the power feed point 103 is advanced from the phase of the high frequency signal supplied to the power feed point 101 by 180 degrees.

The amplifier module 1B may include a phase-shift circuit that shifts the phase of an input high frequency signal on each of the input side of the carrier amplifier 20B and the input side of the peak amplifier 40B.

Furthermore, with the above-mentioned configurations of the carrier amplifier 30B and the peak amplifier 50B, the output impedance of the carrier amplifier 30B at the time of small signal input is higher than that at the time of large signal input. That is, at the time of small signal input, the peak amplifier 50B is in the OFF state, and the output impedance of the carrier amplifier 30B is high. Thus, the carrier amplifier 30B can perform a high-efficiency operation.

In contrast, at the time of large signal input, due to operations of the carrier amplifier 30B and the peak amplifier 50B, a large power signal can be output, and the output impedance of the peak amplifier 50B is low. Thus, signal distortion can be suppressed.

The phase of a high frequency signal input to the carrier amplifier 30B is advanced from the phase of a high frequency signal input to the peak amplifier 50B by 90 degrees, and the signal is supplied to the power feed point 102 by being delayed by 90 degrees due to the ¼ wavelength transmission line 35. Furthermore, the phase of a high frequency signal input to the peak amplifier 50B is delayed by 90 degrees due to the ¼ wavelength transmission line 54, and the signal is supplied to the power feed point 104 by being further delayed by 90 degrees due to the ¼ wavelength transmission line 55. That is, the phase of the high frequency signal supplied to the power feed point 104 is advanced from the phase of the high frequency signal supplied to the power feed point 102 by 180 degrees.

The amplifier module 1B may include a phase-shift circuit that shifts the phase of an input high frequency signal on each of the input side of the carrier amplifier 30B and the input side of the peak amplifier 50B.

An operation of the amplifier module 1B for output power will be described below.

First, as illustrated in FIG. 6A, at the time when the first signal is output (at the time of Max Power output), the carrier amplifiers 20B and 30B and the peak amplifiers 40B and 50B operate (ON). In this case, the output impedance of each of the carrier amplifiers 20B and 30B and the peak amplifiers 40B and 50B is kR_{L}.

Next, as illustrated in FIG. 6B, at the time when the second signal is output (at the time of 9 dB Back off Power output), at which the power is lower than the power at which the first signal is output, the carrier amplifiers 20B and 30B operate (ON) and neither the peak amplifier 40B nor the peak amplifier 50B operates (OFF). In this case, the output impedance of each of the carrier amplifiers 20B and 30B is 4 kR_{L}. At this time, the output impedances of the peak amplifiers 40B and 50B are in the opened state. That is, at the time when the second signal is output, the peak amplifiers 40B and 50B enter the OFF state, and the output impedances of the carrier amplifiers 20B and 30B increase. Thus, the back off amount of 9 dB can be obtained, and the amplifier module 1B can perform a high-efficiency operation.

In FIG. 6C, the horizontal axis represents the power level of a signal output from the amplifier module 1B, and the vertical axis represents the efficiency (power-added efficiency) of the amplifier module 1B.

When the power level of a high frequency signal output from the amplifier module 1B decreases from a first power value (first signal output: I in FIG. 6C) to a second power value (second signal output: II in FIG. 6C), the impedances of the carrier amplifiers 20B and 30B, which are in the ON state, increase. Thus, at the time when the second signal is output, high efficiency can be achieved compared to the case where all the carrier amplifiers 20B and 30B and the peak amplifiers 40B and 50B operate in the ON state (in FIG. 6C, indicated as a Class AB amplifier).

That is, the amplifier module 1B can ensure the back off amount of 9 dB and can thus perform a high-efficiency operation.

Furthermore, the amplifier module 1B according to Modification 1 can exhibit circularly-polarized-wave antenna characteristics. This is because at the times when the first and second signals are output, high frequency signals with a phase difference of 90 degrees are supplied to two power feed points that are adjacent to each other among the power feed points 101 to 104 arranged rotationally symmetrical around the center Pc.

### 4 Configuration of Amplifier Module 1C According to Modification 2

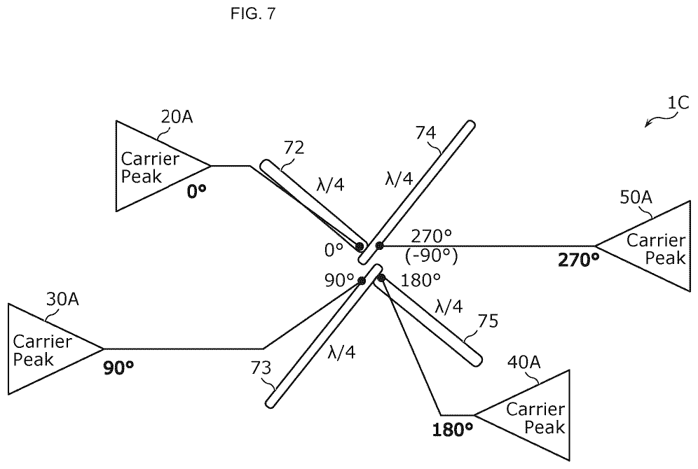

FIG. 7 is a configuration diagram of an amplifier module 1C according to Modification 2. As illustrated in FIG. 7, the amplifier module 1C according to Modification 2 includes antennas 72, 73, 74, and 75 and power amplifiers 20A, 30A, 40A, and 50A. The amplifier module 1C according to this modification is different from the amplifier module 1 according to the exemplary embodiment in configurations of the antennas 72 to 75. Hereinafter, explanation of configurations of the power amplifiers in the amplifier module 1C according to this modification, which are the same as those in the amplifier module 1 according to the exemplary embodiment, will be omitted, and the configurations of the antennas 72 to 75, which are different from those in the amplifier module 1 according to the exemplary embodiment, will be mainly described.

The antennas 72 to 75 are dipole antennas. The length of each of the antennas 72 to 75 is λ/4, where the wavelength at the antenna of a high frequency signal input to the antenna is represented by λ.

A power feed point of the antenna 72 is connected to an output end of the power amplifier 20A. A power feed point of the antenna 73 is connected to an output end of the power amplifier 30A. A power feed point of the antenna 75 is connected to an output end of the power amplifier 40A. A power feed point of the antenna 74 is connected to an output end of the power amplifier 50A.

With this arrangement, the amplifier module 1C can ensure the back off amount of 12 dB and can thus perform a high-efficiency operation.

### 5 Configuration of Amplifier Module 1D According to Modification 3

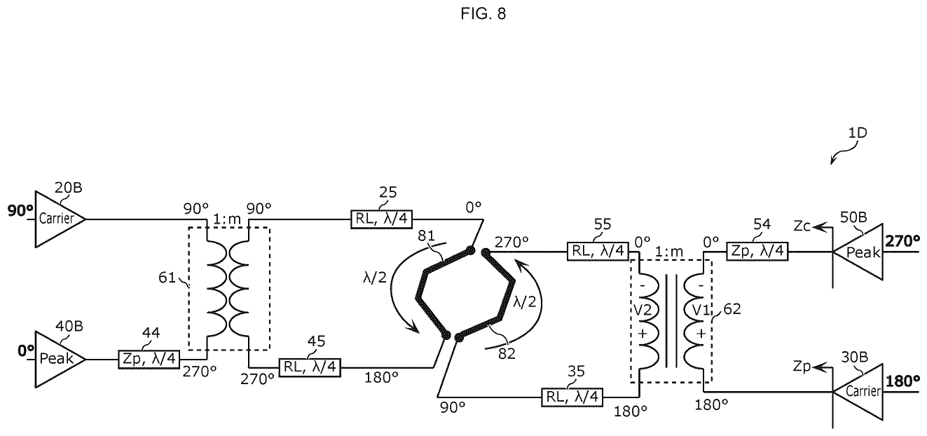

FIG. 8 is a configuration diagram of an amplifier module 1D according to Modification 3. As illustrated in FIG. 8, the amplifier module 1D according to Modification 3 includes antennas 81 and 82, carrier amplifiers 20B and 30B, peak amplifiers 40B and 50B, transformers 61 and 62, and ¼ wavelength transmission lines 25, 35, 44, 45, 54, and 55. The amplifier module 1D according to this modification is different from the amplifier module 1B according to Modification 1 in configurations of the antennas 81 and 82. Hereinafter, explanation of configurations in the amplifier module 1D according to this modification that are the same as those in the amplifier module 1B according to Modification 1 will be omitted, and the configurations of the antennas 81 and 82, which are different from those in the amplifier module 1B according to Modification 1, will be mainly described.

The antennas 81 and 82 are loop antennas. The length of each of the antennas 81 and 82 is λ/2, where the wavelength at the antenna of a high frequency signal input to the antenna is represented by λ.

A power feed point located at one end of the antenna 81 is connected to an output end of the carrier amplifier 20B. A power feed point located at the other end of the antenna 81 is connected to an output end of the peak amplifier 40B. A power feed point located at one end of the antenna 82 is connected to an output end of the carrier amplifier 30B. A power feed point located at the other end of the antenna 82 is connected to an output end of the peak amplifier 50B.

With this arrangement, the amplifier module 1D can ensure the back off amount of 9 dB and can thus perform a high-efficiency operation.

### 6 Advantageous Effects and so on

As described above, the amplifier module 1 according to this exemplary embodiment includes the antenna 10 including the four power feed points 101, 102, 103, and 104, and the four power amplifiers 20, 30, 40, and 50. Output ends of the four power amplifiers 20 to 50 are connected to the four power feed points 101 to 104 in a one-to-one relationship. The four power feed points 101 to 104 are arranged rotationally symmetrical around the center Pc of the antenna 10 when a main surface of the antenna 10 is viewed in plan.

Accordingly, since the four power feed points 101 to 104 are arranged rotationally symmetrical, signals input to power feed points that are adjacent to each other in the rotation direction have a phase difference of 90 degrees. Thus, by turning on and off the four power amplifiers 20 to 50 in accordance with output power, without arranging a synthesis circuit for adjusting phases of output signals from the power amplifiers 20 to 50 and synthesizing the phase-adjusted output signals, impedances of the power amplifiers can be converted without any loss due to synthesis. Consequently, high-efficiency, circularly-polarized-wave antenna characteristics corresponding to back off can be achieved.

Furthermore, for example, in the amplifier module 1, when the main surface of the antenna 10 is viewed in plan, signals input to two power feed points that are adjacent to each other in the rotation direction around the center Pc may have a phase difference of 90 degrees.

Furthermore, for example, in the amplifier module 1A according to the example, the four power amplifiers 20A to 50A may be Doherty amplifiers.

Accordingly, since each of the four power amplifiers 20A to 50A includes a carrier amplifier and a peak amplifier, a large back off amount can be ensured.

For example, in the amplifier module 1A, the four power feed points 101 to 104 are arranged in the order of the power feed points 101, 102, 103, and 104 in the rotation direction around the center Pc, the power amplifier 20A is connected to the power feed point 101 and includes the carrier amplifier 21 and the peak amplifier 22, the power amplifier 30A is connected to the power feed point 102 and includes the carrier amplifier 31 and the peak amplifier 32, the power amplifier 40A is connected to the power feed point 103 and includes the carrier amplifier 41 and the peak amplifier 42, and the power amplifier 50A is connected to the power feed point 104 and includes the carrier amplifier 51 and the peak amplifier 52. When the power level of a high frequency signal output from the antenna 10 is the first power value, the carrier amplifiers 21, 31, 41, and 51 and the peak amplifiers 22, 32, 42, and 52 are in the ON state. When the power level of a high frequency signal output from the antenna 10 is the second power value that is smaller than the first power value, the carrier amplifiers 21, 31, 41, and 51 are in the ON state and the peak amplifiers 22, 32, 42, and 52 are in the OFF state. When the power level of a high frequency signal output from the antenna 10 is the third power value that is smaller than the second power value, the carrier amplifiers 21 and 31 are in the ON state, the carrier amplifiers 41 and 51 are in the OFF state, and the peak amplifiers 22, 32, 42, and 52 are in the OFF state. When the power level of a high frequency signal output from the antenna 10 is the fourth power value that is smaller than the third power value, the carrier amplifier 21 is in the ON state, the carrier amplifiers 31, 41, and 51 are in the OFF state, and the peak amplifiers 22, 32, 42, and 52 are in the OFF state.

Accordingly, since the amplifier module 1A ensures the back off amount of 6 dB in each stage, that is, 18 dB in total, the amplifier module 1A can perform a high-efficiency operation while reducing degradation in the efficiency to the minimum level. Furthermore, since high frequency signals with a phase difference of 90 degrees are supplied to two power feed points that are adjacent to each other among the power feed points 101 to 104 arranged rotationally symmetrical around the center Pc at the first to fourth power values, circularly-polarized-wave antenna characteristics can be achieved.

Furthermore, in each of the amplifier modules 1 and 1A, the antenna 10 may include the dielectric substrate 11, the ground planar conductor 13, and the power-feed planar conductor 12 including the four power feed points 101 to 104, the dielectric substrate 11 being placed between the ground planar conductor 13 and the power-feed planar conductor 12. The distance between each of the four power feed points 101 to 104 and the center Pc may be λ/4, where the wavelength at the dielectric substrate 11 of a high frequency signal is represented by λ.

Accordingly, the phase difference between two signals input to two power feed points that are adjacent to each other in the rotation direction can be set to 90 degrees with high precision, a harmonic wave distortion component can be suppressed with high accuracy.

Furthermore, the communication apparatus 3 according to the exemplary embodiment includes the signal processing circuit 2 that processes a high frequency signal and the amplifier module 1 that is connected to the signal processing circuit 2.

Accordingly, advantageous effects of the amplifier module 1 can be achieved with the communication apparatus 3.

### Other Embodiments

An amplifier module and a communication apparatus according to the present disclosure have been described above on the basis of an exemplary embodiment. However, the amplifier module and the communication apparatus according to the present disclosure are not limited to the exemplary embodiment described above. Other exemplary embodiments obtained by combining desired component elements in the embodiment described above, modifications obtained by making various modifications conceived by those skilled in the art to the forgoing exemplary embodiment without departing from the spirit of the present disclosure, and various types of equipment including the amplifier module and the communication apparatus described above are also included in the present disclosure.

For example, in the circuit configurations of the amplifier module and the communication apparatus according to the foregoing exemplary embodiment, other circuit elements, other wires, and the like may be added into paths connecting circuit elements and signal paths disclosed in drawings.

Characteristics of amplifier modules and communication apparatuses described above in the foregoing embodiments and modifications will be described below.

<1>

An amplifier module comprising:
an antenna including four power feed points; and
four power amplifiers,
wherein output ends of the four power amplifiers are connected to the four power feed points in a one-to-one relationship, and
wherein the four power feed points are arranged rotationally symmetrically around a center of the antenna when a main surface of the antenna is viewed in plan.

<2>

The amplifier module according to <1>, wherein when the main surface of the antenna is viewed in plan, signals input to two power feed points that are adjacent to each other in a rotation direction around the center have a phase difference of 90 degrees.

<3>

The amplifier module according to <1> or <2>, wherein the four power amplifiers are Doherty amplifiers.

<4>

The amplifier module according to <3>,
wherein the four power feed points are arranged in the order of a first power feed point, a second power feed point, a third power feed point, and a fourth power feed point in a rotation direction around the center,
wherein, out of the four power amplifiers, a first power amplifier is connected to the first power feed point and includes a first carrier amplifier and a first peak amplifier,
wherein, out of the four power amplifiers, a second power amplifier is connected to the second power feed point and includes a second carrier amplifier and a second peak amplifier,
wherein, out of the four power amplifiers, a third power amplifier is connected to the third power feed point and includes a third carrier amplifier and a third peak amplifier,
wherein, out of the four power amplifiers, a fourth power amplifier is connected to the fourth power feed point and includes a fourth carrier amplifier and a fourth peak amplifier,
wherein, when a power level of a high frequency signal output from the antenna is a first power value, the first to fourth carrier amplifiers and the first to fourth peak amplifiers are in an ON state,
wherein, when the power level of a high frequency signal output from the antenna is a second power value that is smaller than the first power value, the first to fourth carrier amplifiers are in the ON state and the first to fourth peak amplifiers are in an OFF state,
wherein, when the power level of a high frequency signal output from the antenna is a third power value that is smaller than the second power value, the first and second carrier amplifiers are in the ON state, the third and fourth carrier amplifiers are in the OFF state, and the first to fourth peak amplifiers are in the OFF state, and
wherein, when the power level of a high frequency signal output from the antenna is a fourth power value that is smaller than the third power value, the first carrier amplifier is in the ON state, the second to fourth carrier amplifiers are in the OFF state, and the first to fourth peak amplifiers are in the OFF state.

<5>

The amplifier module according to any one of <1> to <4>,
wherein the antenna includes
   a dielectric substrate,
   a ground planar conductor, and a power-feed planar conductor including the four power feed points, the dielectric substrate being placed between the ground planar conductor and the power-feed planar conductor, and
wherein a distance between each of the four power feed points and the center is λ/4, where a wavelength at the dielectric substrate of a high frequency signal input to the antenna is represented by λ.

<6>

A communication apparatus comprising:
a signal processing circuit that processes a high frequency signal; and
the amplifier module according to any one of <1> to <5> that is connected to the signal processing circuit.

<7>

The amplifier module according to any one of <1> to <5>, wherein the dielectric substrate is a low temperature co-fired ceramics (LTCC).

<8>

The amplifier module according to any one of <1> to <5>, wherein the four power amplifiers each include a heterojunction bipolar transistor (HBT).

<9>

The amplifier module according to anyone of <1> to <5>, wherein the four power amplifiers each include a metal-oxide-semiconductor field effect transistor (MOSFET).

<10>

The amplifier module according to any one of <1> to <5>, wherein at least one of the four amplifiers includes an amplifier that operates as a class A amplifier.

<11>

The amplifier module according to any one of <1> to <5>, wherein at least one of the four power amplifiers includes an amplifier that operates as a class AB amplifier.

<12>

The amplifier module according to <10>, wherein the amplifier that operates as a class A amplifier is a carrier amplifier.

<13>

The amplifier module according to <11>, wherein the amplifier that operates as a class AB amplifier is a carrier amplifier.

<14>

The amplifier module according to any one of <1> to <5>, wherein at least one of the four power amplifiers includes an amplifier that operates as a class C amplifier.

<15>

The amplifier module according to <14>, wherein the amplifier that operates as a class C amplifier is a peak amplifier.

<16>

The amplifier module according to any one of <1> to <5>, wherein the antenna is a loop antenna.

<17>

The amplifier module according to any one of <1> to <5>, wherein the antenna is formed from a planar conductor.

<18>

The amplifier module according to <17>, wherein the center of the antenna is a center of gravity of the planar conductor.

<19>

The amplifier module according to any one of <1> to <5>, wherein the antenna includes a plurality of antennas.

<20>

The amplifier module according to <19>, wherein each of the plurality of antennas includes one of the four power feed points.

The present disclosure can be widely used as an amplifier module or a communication apparatus that is arranged in a front end part capable of supporting multiple bands in communication equipment such as a cellular phone.

What is claimed is:

1. An amplifier module comprising:
an antenna including four power feed points; and
four power amplifiers,
wherein output ends of the four power amplifiers are connected to the four power feed points in a one-to-one relationship, and
wherein the four power feed points are arranged rotationally symmetrically around a center of the antenna when a main surface of the antenna is viewed in plan.

2. The amplifier module according to claim 1, wherein when the main surface of the antenna is viewed in plan, signals input to two power feed points that are adjacent to each other in a rotation direction around the center have a phase difference of 90 degrees.

3. The amplifier module according to claim 1, wherein the four power amplifiers are Doherty amplifiers.

4. The amplifier module according to claim 3,
wherein the four power feed points are arranged in the order of a first power feed point, a second power feed point, a third power feed point, and a fourth power feed point in a rotation direction around the center,
wherein, out of the four power amplifiers, a first power amplifier is connected to the first power feed point and includes a first carrier amplifier and a first peak amplifier,
wherein, out of the four power amplifiers, a second power amplifier is connected to the second power feed point and includes a second carrier amplifier and a second peak amplifier,
wherein, out of the four power amplifiers, a third power amplifier is connected to the third power feed point and includes a third carrier amplifier and a third peak amplifier,
wherein, out of the four power amplifiers, a fourth power amplifier is connected to the fourth power feed point and includes a fourth carrier amplifier and a fourth peak amplifier,
wherein, when a power level of a high frequency signal output from the antenna is a first power value, the first to fourth carrier amplifiers and the first to fourth peak amplifiers are in an ON state,
wherein, when the power level of a high frequency signal output from the antenna is a second power value that is smaller than the first power value, the first to fourth carrier amplifiers are in the ON state and the first to fourth peak amplifiers are in an OFF state,
wherein, when the power level of a high frequency signal output from the antenna is a third power value that is smaller than the second power value, the first and second carrier amplifiers are in the ON state, the third and fourth carrier amplifiers are in the OFF state, and the first to fourth peak amplifiers are in the OFF state, and
wherein, when the power level of a high frequency signal output from the antenna is a fourth power value that is smaller than the third power value, the first carrier amplifier is in the ON state, the second to fourth carrier amplifiers are in the OFF state, and the first to fourth peak amplifiers are in the OFF state.

5. The amplifier module according to claim 1,
wherein the antenna includes
a dielectric substrate,
a ground planar conductor, and a power-feed planar conductor including the four power feed points, the dielectric substrate being placed between the ground planar conductor and the power-feed planar conductor, and
wherein a distance between each of the four power feed points and the center is λ/4, where a wavelength at the dielectric substrate of a high frequency signal input to the antenna is represented by λ.

6. A communication apparatus comprising:
a signal processing circuit that processes a high frequency signal; and
the amplifier module according to claim 1 that is connected to the signal processing circuit.

7. The amplifier module according to claim 5, wherein the dielectric substrate is a low temperature co-fired ceramics (LTCC).

8. The amplifier module according to claim 1, wherein the four power amplifiers each include a heterojunction bipolar transistor (HBT).

9. The amplifier module according to claim 1, wherein the four power amplifiers each include a metal-oxide-semiconductor field effect transistor (MOSFET).

10. The amplifier module according to claim 1, wherein at least one of the four amplifiers includes an amplifier that operates as a class A amplifier.

11. The amplifier module according to claim 1, wherein at least one of the four power amplifiers includes an amplifier that operates as a class AB amplifier.

12. The amplifier module according to claim 10, wherein the amplifier that operates as a class A amplifier is a carrier amplifier.

13. The amplifier module according to claim 11, wherein the amplifier that operates as a class AB amplifier is a carrier amplifier.

14. The amplifier module according to claim 1, wherein at least one of the four power amplifiers includes an amplifier that operates as a class C amplifier.

15. The amplifier module according to claim 14, wherein the amplifier that operates as a class C amplifier is a peak amplifier.

16. The amplifier module according to claim 1, wherein the antenna is a loop antenna.

17. The amplifier module according to claim 1, wherein the antenna is formed from a planar conductor.

18. The amplifier module according to claim 17, wherein the center of the antenna is a center of gravity of the planar conductor.

19. The amplifier module according to claim 1, wherein the antenna includes a plurality of antennas.

20. The amplifier module according to claim 19, wherein each of the plurality of antennas includes one of the four power feed points.
